(19) United States
(12) Patent Application Publication
(10) Pub. No.: US 2026/0129841 A1
(43) Pub. Date: May 7, 2026

(54) SEMICONDUCTOR DEVICE AND METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Huilong ZHU, Poughkeepsie, NY (US); Xianyu CHEN, Beijing (CN); Yongkui ZHANG, Beijing (CN); Qi WANG, Beijing (CN); Jun LUO, Beijing (CN); Tianchun YE, Beijing (CN)

(21) Appl. No.: 18/974,900

(22) Filed: Dec. 10, 2024

(30) Foreign Application Priority Data
Nov. 1, 2024 (CN) 202411554154.5

(51) Int. Cl. H10B 12/00

(52) U.S. Cl. CPC H10B 12/482; H10B 12/05; H10B 12/315

(57) ABSTRACT

A semiconductor device includes: a substrate; transistors on the substrate, a channel region being between adjacent transistors, the transistor including a surrounding gate layer, a source layer, a drain layer, and a body contact layer, a body contact cavity being between the source layer and the drain layer, and the body contact layer being in the body contact cavity; a bit line at a bottom of the channel region and coupled to the transistor; a word line on a dielectric layer of the channel region and perpendicular to the bit line, wherein the dielectric layer covers the substrate and the bit line; and a base line in the body contact cavity and the channel region, wherein the base line is in contact with the body contact layer and isolated from the source layer, the drain layer, and the word line, and the base line is parallel to the bit line.

This application claims the benefit of priority to Chinese Patent Application No. 202411554154.5, filed on Nov. 1, 2024. The entire contents of this application are hereby incorporated herein by reference.

### TECHNICAL FIELD

The present disclosure relates to a field of semiconductor technology, and in particular, to a semiconductor device and a method of manufacturing a semiconductor device.

### BACKGROUND

In fields of Dynamic Random Access Memory (DRAM), in the mainstream development direction, the vertical transistor structure with source, gate, and drain vertically arranged is used as the DRAM memory unit with 4F² architecture and a high memory density, so as to improve the integration of DRAM.

### SUMMARY

According to an aspect of the present disclosure, a semiconductor device is provided, including: a substrate; a plurality of transistors on the substrate, where a channel region is between adjacent transistors among the plurality of transistors, each of the plurality of transistors includes a surrounding gate layer, a source layer, a drain layer, and a body contact layer, the surrounding gate layer is adjacent to the source layer and the drain layer, a body contact cavity is formed between the source layer and the drain layer, an opening of the body contact cavity is located on a side of the transistor away from the surrounding gate layer, and the body contact layer is located within the body contact cavity; a bit line at a bottom of the channel region and extending in a second direction, where the transistor is coupled to the bit line; a word line on a dielectric layer of the channel region, extending in a first direction and perpendicular to the bit line, where the dielectric layer covers the substrate and the bit line; and a base line in the body contact cavity and the channel region, where the base line is in contact with the body contact layer and isolated from the source layer, the drain layer, and the word line, and the base line extends in the second direction and is parallel to the bit line.

For example, each of the plurality of transistors further includes: a channel layer on a side of the transistor away from the opening of the body contact cavity, where the channel layer includes a first part, a second part, and a third part, the first part of the channel layer is connected to the body contact layer, the third part of the channel layer is connected to the source layer and the drain layer, and the second part of the channel layer is located between the first part of the channel layer and the third part of the channel layer, and where a doping concentration of the first part of the channel layer is greater than a doping concentration of the second part of the channel layer in a vertical direction of the semiconductor device.

For example, a height of the first part of the channel layer is greater than a height of the body contact layer in the vertical direction of the semiconductor device, and a doping type of the channel layer is same as a doping type of the source layer, the drain layer, or the body contact layer connected to the channel layer.

For example, the channel region extends in the second direction.

For example, widths of the plurality of transistors in the first direction are equal to each other, distances between the transistors among the plurality of transistors in the first direction are equal to each other, and distances between bit lines in the first direction are equal to each other, and the distance between the bit lines is less than 50 nm.

According to another aspect of the present disclosure, a method of manufacturing a semiconductor device is provided, including: forming a plurality of transistors arranged in a matrix on a substrate, where a channel region is formed between adjacent transistors among the plurality of transistors, each of the plurality of transistors includes a surrounding gate layer, a source layer, a drain layer, and a body contact layer, the surrounding gate layer is adjacent to the source layer and the drain layer, a body contact cavity is formed between the source layer and the drain layer, an opening of the body contact cavity is located on a side of the transistor away from the surrounding gate layer, and the body contact layer is located within the body contact cavity; forming a bit line extending in a second direction at a bottom of the channel region, and depositing a dielectric layer to cover the substrate and the bit line; forming a word line extending in a first direction and perpendicular to the bit line on the dielectric layer; and forming a base line in the body contact cavity and the channel region, where the base line extends in the second direction and is parallel to the bit line, the base line is in contact with the body contact layer, and the base line is isolated from the source layer, the drain layer, and the word line.

For example, forming the plurality of transistors arranged in the matrix on the substrate and forming the bit line extending in the second direction at the bottom of the channel region includes: preparing a device precursor on the substrate, where the device precursor includes a plurality of source/drain structures distributed in the first direction and a first etching sacrificial layer, a first trench or a second trench deep to the substrate is provided between adjacent source/drain structures among the plurality of source/drain structures, the first etching sacrificial layer covers the source/drain structure and fills the first trench and the second trench, each of the plurality of source/drain structures includes the source layer, the drain layer, a body contact sacrificial layer, and the body contact layer, the body contact sacrificial layer is located between the source layer and the drain layer, the body contact layer is sandwiched in the body contact sacrificial layer, and a channel layer is formed on an inner wall of the first trench; etching the first etching sacrificial layer and the source/drain structure located on a designated side of the second trench according to a device region, and retaining a part of the source layer on the substrate as the bit line; etching a remaining part of the first etching sacrificial layer, and depositing the dielectric layer on the substrate and the bit line to form the channel region; removing the body contact sacrificial layer in the source/drain structure, so as to form the body contact cavity having the opening on a side of the source/drain structure away from the channel layer; and depositing a high dielectric constant material and a metal gate material in the body contact cavity and on a surface of the source/drain structure, and removing a part of the high dielectric constant material and a part of the metal gate material in the body contact cavity to have a predetermined width and a part of the high dielectric constant material and a part of the metal gate material on the source/drain structure close to the opening of the body contact cavity to obtain the surrounding gate layer, so as to form the transistor, where the body contact layer is exposed outside the surrounding gate layer.

For example, the preparing a device precursor on the substrate includes: sequentially growing, in a vertical direction of the semiconductor device, the source layer, a first body contact sacrificial layer, the body contact layer, a second body contact sacrificial layer, and the drain layer on the substrate, so as to form a stack; forming a patterned structure on the stack by using a patterning process, and fabricating a spacer on both sides of the patterned structure, where the patterned structure includes a mandrel sacrificial layer and a second etching sacrificial layer sequentially grown; etching the stack with the spacer as a barrier, so as to form the first trench deep to the substrate; epitaxially growing the channel layer on the inner wall of the first trench; polishing the second etching sacrificial layer to expose the mandrel sacrificial layer, and removing the mandrel sacrificial layer; etching the stack with the spacer obtained after removing the mandrel sacrificial layer as a mask, so as to form the second trench deep to the substrate and the source/drain structure; and depositing the first etching sacrificial layer on the first trench, the second trench, and the source/drain structure to form the device precursor.

For example, the epitaxially growing the channel layer on the inner wall of the first trench includes: epitaxially growing a single crystal channel on the inner wall of the first trench; and performing a thermal annealing treatment on the single crystal channel to drive dopants in the stack into the single crystal channel, so as to form the channel layer.

For example, an angle between the device region and the second direction is in a range of 55° to 65°.

For example, a width of the mandrel sacrificial layer in the first direction is a distance between the transistors in the first direction, a width of the transistor in the first direction is a sum of a width of the spacer in the first direction and a thickness of the channel layer in the first direction, a width of the first trench in the first direction is a sum of the width of the mandrel sacrificial layer and twice the thickness of the channel layer, and the distance between the transistors or the width of the transistor is less than 50 nm.

For example, the forming a word line extending in a first direction and perpendicular to the bit line on the dielectric layer of the channel region includes: sequentially depositing the high dielectric constant material and the metal gate material on the dielectric layer; and etching the high dielectric constant material and the metal gate material on the dielectric layer according to a word line region, so as to form the word line.

For example, the forming a base line in the body contact cavity and the channel region includes: growing an etching stop layer on the word line and the surrounding gate layer; removing a part of the etching stop layer covering the word line, so as to form a gap exposing the word line; filling the body contact cavity and the gap with an isolation layer, and keeping the body contact layer exposed outside the isolation layer; depositing a conductive material on the transistor and the channel region; and removing a part of the conductive material in contact with the transistor and a part of the conductive material covering the etching stop layer, so as to form the base line.

The above description is an overview of the technical solution of the present disclosure. In order to have a clearer understanding of the technical means of the present disclosure, it may be implemented according to the content of the specification. In order to make the above and other purposes, features, and advantages of the present disclosure clearer and understandable, the specific implementation methods of the present disclosure are listed below.

### BRIEF DESCRIPTION OF THE DRAWINGS

The accompanying drawings described herein are intended to provide further understanding of the present disclosure and constitute a part of the present disclosure. The illustrative embodiments and their descriptions of the present disclosure are used to describe the present disclosure and do not constitute undue limitation of the present disclosure. In the accompanying drawings:

FIG. 1 shows a partial cross-sectional view of a semiconductor device provided in embodiments of the present disclosure in a first direction;

FIG. 2 shows a cross-sectional view of a stack provided in embodiments of the present disclosure in the first direction;

FIG. 3 shows a cross-sectional view of a structure in the first direction after fabricating a spacer provided in embodiments of the present disclosure;

FIG. 4 shows a cross-sectional view of a structure in the first direction after forming a first trench provided in embodiments of the present disclosure;

FIG. 5 shows a cross-sectional view of a structure in the first direction after epitaxially growing a single crystal channel provided in embodiments of the present disclosure;

FIG. 6 shows a cross-sectional view of a structure in the first direction after growing a channel layer provided in embodiments of the present disclosure;

FIG. 7 shows a partial cross-sectional view of a device precursor provided in embodiments of the present disclosure in the first direction;

FIG. 8 shows a top view of a device precursor provided in embodiments of the present disclosure;

FIG. 9 shows a cross-sectional view of a structure in the first direction after forming a channel region provided in embodiments of the present disclosure;

FIG. 10 shows a cross-sectional view of a structure in a photoresist angle after removing a body contact sacrificial layer provided in embodiments of the present disclosure;

FIG. 11 shows a cross-sectional view of a structure in the first direction after sequentially depositing a high dielectric constant material and a conductive material on a dielectric layer provided in embodiments of the present disclosure;

FIG. 12 shows a cross-sectional view of a structure in the first direction after forming a transistor and a word line provided in embodiments of the present disclosure;

FIG. 13 shows a cross-sectional view of a structure in the first direction after filling an isolation layer provided in embodiments of the present disclosure; and

FIG. 14 shows a cross-sectional view of a structure in the first direction after depositing a base line provided in embodiments of the present disclosure.

### DETAILED DESCRIPTION OF EMBODIMENTS

In the following, the present disclosure will be described in detail with reference to accompanying drawings and in conjunction with embodiments. It should be noted that in a case of no conflict, embodiments in the present disclosure and the features in embodiments mat be combined with each other.

Embodiments of the present disclosure are described in detail below, and examples of embodiments are shown in the accompanying drawings, where same or similar reference numerals from beginning to end represent same or similar elements or elements with same or similar functions. Embodiments described below with reference to the accompanying drawings are exemplary and are used to describe the present disclosure, and cannot be interpreted as limiting the present disclosure.

Those skilled in the art may understand that, unless specifically stated, the singular forms “a”, “an”, “and”, “this” used herein may also include plural forms. It should be further understood that the term “include” used in the specification of the present disclosure refers to the presence of features, integers, steps, operations, elements, and/or components, but does not exclude the presence or addition of one or more other features, integers, steps, operations, elements, components, and/or a combination thereof. In addition, the term “and/or” used herein includes all or any combination of one or more associated listed items. The terms “first”, “second”, “third,” etc. used herein are for descriptive purposes only and should not be understood as indicating or implying relative importance. The term “plurality of” used herein refers to two or more, unless otherwise specified. The terms “installation”, “connection”, “connected”, “fixation” used herein should be broadly understood. For example, “connection” may be a fixed connection, a detachable connection, or an integral connection. ‘Connected’ may be directly connected or indirectly connected through an intermediate medium. When a component is “connected” to a further component, it may be directly connected to the further component, or there may be an intermediate component. Those ordinary skilled in the art may understand the specific meanings of the above terms in embodiments of the present disclosure according to the specific situation. The orientation or positional relationships indicated by terms “up”, “down”, “left”, “right”, “front”, “back”, etc. used herein are the orientation or positional relationships shown in the accompanying drawings, which are only for the convenience of describing embodiments of the present disclosure and simplifying the description, and do not indicate or imply that the device or unit referred to must have a specific orientation, be constructed and operated in a specific orientation. Therefore, they cannot be understood as limiting embodiments of the present disclosure.

Exemplary embodiments according to the present disclosure will be described in more detail with reference to the accompanying drawings. However, these exemplary embodiments may be implemented in various forms and should not be interpreted as limited to embodiments described herein. It should be understood that these embodiments are provided to ensure thorough and complete disclosure of the present disclosure, and to fully convey the concept of these exemplary embodiments to those skilled in the art.

Generally, the Floating Body Effect (FBE) and the Gate Induced Drain Leakage (GIDL) of existing vertical channel transistors may lead to an increase in the off-state current of devices, which to some extent hinders the further application of existing vertical channel transistors in high-performance DRAM.

The present disclosure provides a semiconductor device and a method of manufacturing a semiconductor device, which achieve an ultra-low off-state current in a wide range of gate control voltages while achieving further miniaturization of DRAM memory cells by leading out the base line through the body contact in the vertical channel region.

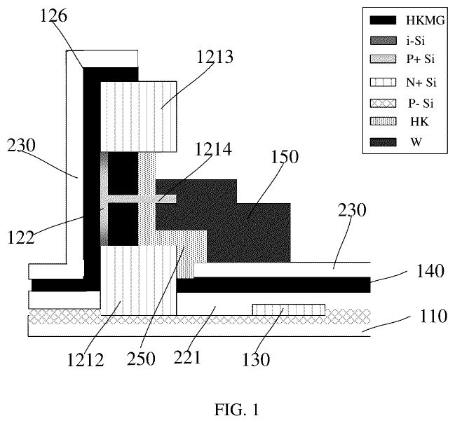

In an embodiment, a semiconductor device is provided, as shown in FIG. 1, taking the semiconductor device as a DRAM transistor array as an example for description. The semiconductor device includes a substrate 110, transistors (not shown in the figure), a bit line 130, a word line 140, and a base line 150.

As shown in FIG. 1 and FIG. 9, a plurality of transistors are on the substrate 110 and arranged in a matrix form. A channel region 190 is provided between adjacent transistors among the plurality of transistors, and the channel region 190 extends in the second direction.

The transistor includes a surrounding gate layer 126, a source layer 1212, a drain layer 1213, and a body contact layer 1214. The surrounding gate layer 126 is adjacent to the source layer 1212 and the drain layer 1213. A body contact cavity is between the source layer 1212 and the drain layer 1213. An opening of the body contact cavity is located on a side of the transistor away from the surrounding gate layer 126. The body contact layer 1214 is located in the body contact cavity and extends in the second direction.

The bit line 130 is located at a bottom of the channel region 190 and extends in the second direction. The transistor is coupled to the bit line 130. In some embodiments, distances between bit lines 130 in the first direction may be equal to each other, and the distance is less than 50 nm.

The word line 140 is located on a dielectric layer 221 of the channel region 190. The word line 140 extends in a first direction and is perpendicular to the bit line 130. The dielectric layer 221 covers the substrate 110 and the bit line 130, so as to isolate the word line 140 from the substrate 110 and the bit line 130.

The base line 150 is located in the body contact cavity and the channel region 190. The base line 150 is in contact with the body contact layer 1214 and isolated from the source layer 1212, the drain layer 1213, and the word line 140. The base line 150 extends in the second direction and is parallel to the bit line 130.

In this embodiment, the base line is led out from the internal body contact region of the transistor to ensure that the base line is connected to the transistor, and the base line is used as a carrier channel to transport carriers induced by different vertical transistors. Through the above technical solution, on the one hand, the problem of unstable threshold voltage of vertical transistors caused by the presence of excess charge carriers is avoided, so that the device has an ultra-low off-state current in a wide range of gate control voltages, the floating body effect of the semiconductor structure is effectively reduced, forward conduction of the parasitic PN junction is prevented, and the leakage current is significantly reduced; on the other hand, the source, the gate, and the drain are provided in the vertical direction perpendicular to the substrate surface, and a part of the base line is located in the internal body contact region of the transistor, without occupying additional area, while the bit line, the word line, and the base line are provided in an overlapping manner in the channel region in the first direction, and the bit line, the word line, and the base line are isolated by the isolation material, eliminating the inherent distance between the bit line, the word line, and the base line in the DRAM array structure of existing gate-all-around transistors, which is conducive to the miniaturization of semiconductor devices.

It may be understood that, a distance between the bit line and the transistor in the first direction is identical to a width of the transistor in the first direction, and a distance between the transistors among the plurality of transistors is less than 50 nm, such as 10 nm, 15 nm, 26 nm etc., which facilitates the reduction of the size of the semiconductor device.

For example, the substrate may be made of semiconductor materials containing silicon, such as a combination or a plurality layers of silicon, single crystal silicon, polycrystalline silicon, amorphous silicon, silicon germanium, single crystal silicon germanium, polycrystalline silicon germanium, and carbon doped silicon. Taking a P-well/NMOS device as an example, P-type well region implantation is performed on the single crystal silicon to form a substrate with a P-type well region.

The body contact layer may be made of conductive materials such as metal, metal nitride, metal silicide, etc., for example, heavily doped P-type silicon (P+Si). The Bit line may be made of a semiconductor material, a metal-based material, or a combination thereof, such as heavily doped N-type silicon. The word line, the base line, and the surrounding gate layer may include silicon oxide, silicon nitride, silicon nitride oxide, high dielectric material, or a combination thereof. The source layer and the drain layer may be made of semiconductor materials doped with P-type or N-type impurities. For example, for p-type devices, the source layer and the drain layer may include p-type doped silicon or germanium silicon, while for n-type devices, the source layer and the drain layer may include n-type doped silicon or germanium silicon.

In an embodiment, as shown in FIG. 1, the transistor is provided with a channel layer 122 on a side of the surrounding gate layer 126 (the side of the transistor away from the opening of the body contact cavity). The channel layer 122 may be connected to the source layer 1212, the drain layer 1213, and the body contact layer 1214, so as to form a sidewall of the body contact cavity away from the opening. At least a part of the channel layer 122 is located between the surrounding gate layer 126 and at least one of the source layer 1212, the drain layer 1213, or the body contact layer 1214.

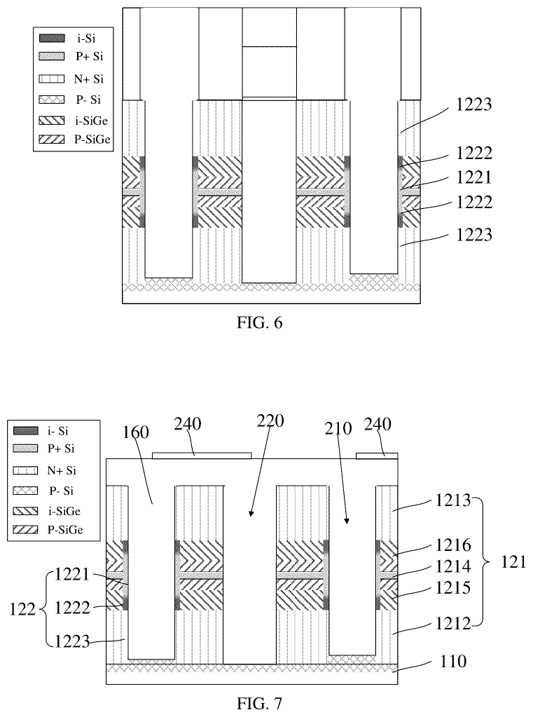

For example, as shown in FIG. 6, a doping concentration of the first part 1221 of the channel layer is greater than a doping concentration of the second part 1222 of the channel layer in a vertical direction of the semiconductor device, the first part 1221 of the channel layer is connected to the body contact layer 1214, the third part 1223 of the channel layer is connected to the source layer 1212 and the drain layer 1213, and the second part 1222 of the channel layer is located between the first part 1221 of the channel layer and the third part 1223 of the channel layer. The thickness of the channel layer 122 is in a range of 3 nm to 20 nm, such as 5 nm, 8 nm, 10 nm, 15 nm, etc., which may be set reasonably according to the size of the transistor.

It may be understood that the channel layer may be formed through epitaxial growth.

In this embodiment, due to the high doping concentration of the first part of the channel layer and the low doping concentration of the second part of the channel layer, the second part of the channel layer with the low doping concentration may reduce an energy band barrier in the channel direction to obtain a smoother electric field and energy band, thereby suppressing the inter-band tunneling and reducing gate-induced drain leakage.

It is worth mentioning that, as shown in FIG. 6, in the vertical direction of the semiconductor device, the height of the first part 1221 of the channel layer is greater than the height of the body contact layer 1214. In this way, due to the connection between the body contact layer 1214 and the first part 1221 with the high doping concentration, while ensuring that the first part 1221 of the channel layer does not affect a region where the gate-induced drain leakage generates and there may be a significant depletion region, the control of the off-state current of the semiconductor device by the bias voltage of the body contact layer is achieved.

Furthermore, the channel layer may be symmetrical or asymmetrical with respect to the body contact layer, that is, the extension heights of the first, second, and third parts of the channel layer located above the body contact layer may be the same as or different from those of the corresponding first, second, and third parts of the channel layer located below the body contact layer.

In an embodiment, a method of manufacturing a semiconductor device is provided, including step 301 to step 304.

In step 301, a plurality of transistors arranged in a matrix are formed on a substrate.

A channel region is formed between adjacent transistors among the plurality of transistors. The transistor includes a surrounding gate layer, a source layer, a drain layer, and a body contact layer. The surrounding gate layer is adjacent to the source layer and the drain layer, and the surrounding gate layer is isolated from the source layer and the drain layer by dielectric. A body contact cavity is formed between the source layer and the drain layer. An opening of the body contact cavity is located on a side of the transistor away from the surrounding gate layer. The body contact layer is located within the body contact cavity, so as to form a Body-Contacted Vertical Channel Transistor (BCVCT).

In step 302, a bit line extending in a second direction is formed at a bottom of the channel region, and a dielectric layer is deposited.

The dielectric layer covers the substrate and the bit line.

In this embodiment, the bit line is fabricated at the bottom of the channel region between the transistors, which not only ensures the connection between the transistor and the bit line, but also combines the layout of bit lines with transistors distributed in a matrix, so that the bit lines may be connected to a plurality of transistors in a regular manner, thereby reducing the space occupied by the bit lines in the chip and optimizing the space utilization of semiconductor devices. Then, the dielectric layer is deposited in the channel region, and the dielectric layer may cover the substrate and the bit lines in the channel region, so as to effectively isolate the transistor and bit lines from other conductive structures, thereby reducing the parasitic capacitance and the resistance, and preventing the electromagnetic interference and the signal crosstalk, and improving the operating efficiency and the response speed of semiconductor devices.

Furthermore, as a refinement and extension of the specific implementation method of the above embodiment, in order to fully describe the specific implementation process of this embodiment, the step 301 and the step 302, that is, forming the plurality of transistors arranged in the matrix on the substrate and forming the bit line extending in the second direction at the bottom of the channel region include the following steps: preparing a device precursor on the substrate; etching a source/drain structure located on a designated side of a second trench and a first etching sacrificial layer according to a device region, and retaining a part of the source layer on the substrate as the bit line; etching a remaining part of the first etching sacrificial layer, and depositing the dielectric layer on the substrate and the bit line, so as to form the channel region; removing the body contact sacrificial layer in the source/drain structure, so as to form the body contact cavity having the opening on a side of the source/drain structure away from the channel layer; depositing a high dielectric constant material and a metal gate material in the body contact cavity and on a surface of the source/drain structure, and removing a part of the high dielectric constant material and a part of the metal gate material in the body contact cavity to have a predetermined width and a part of the high dielectric constant material and a part of the metal gate material on the source/drain structure close to the opening of the body contact cavity to obtain the surrounding gate layer, so as to form the transistor.

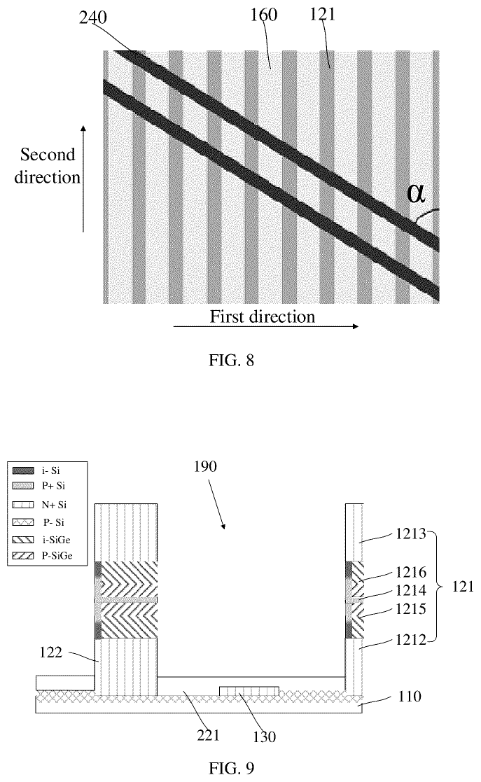

The body contact layer is exposed outside the surrounding gate layer, so as to connect to the base line subsequently. As shown in FIG. 7, FIG. 8 and FIG. 9, the device precursor includes a plurality of source/drain structures 121 distributed in the first direction and a first etching sacrificial layer 160. A first trench 210 or a second trench 220 deep to the substrate 110 is provided between adjacent source/drain structures 121 among the plurality of source/drain structures 121. The first etching sacrificial layer 160 covers the source/drain structure 121 and fills the first trench 210 and the second trench 220. The source/drain structure 121 includes the source layer 1212, the drain layer 1213, a body contact sacrificial layer, and the body contact layer 1214. The body contact sacrificial layer is located between the source layer 1212 and the drain layer 1213. The body contact layer 1214 is sandwiched in the body contact sacrificial layer. The channel layer 122 is formed on an inner wall of the first trench 210. For example, an angle between the device region and the second direction is in a range of 55° to 65°, which may be flexibly determined according to process conditions and product requirements, and is not limited in embodiments of the present disclosure.

Furthermore, preparing the device precursor on the substrate may, for example, include: sequentially growing, in a vertical direction of the semiconductor device, the source layer, a first body contact sacrificial layer, the body contact layer, a second body contact sacrificial layer, and the drain layer on the substrate, so as to form a stack; forming a patterned structure on the stack by using a patterning process, and fabricating a spacer on both sides of the patterned structure, where the patterned structure includes a mandrel sacrificial layer and a second etching sacrificial layer sequentially grown; etching the stack with the spacer as a barrier, so as to form the first trench deep to the substrate; epitaxially growing the channel layer on the inner wall of the first trench; polishing the second etching sacrificial layer to expose the mandrel sacrificial layer, and removing the mandrel sacrificial layer; etching the stack with the spacer obtained after removing the mandrel sacrificial layer as a mask, so as to form the second trench deep to the substrate and the source/drain structure; and depositing the first etching sacrificial layer on the first trench, the second trench, and the source/drain structure to form the device precursor. The patterning process includes steps such as deposition, exposure and etching.

Furthermore, epitaxially growing the channel layer on the inner wall of the first trench may, for example, include: epitaxially growing a single crystal channel on the inner wall of the first trench; and performing a thermal annealing treatment on the single crystal channel to drive dopants in the stack into the single crystal channel, so as to form the channel layer.

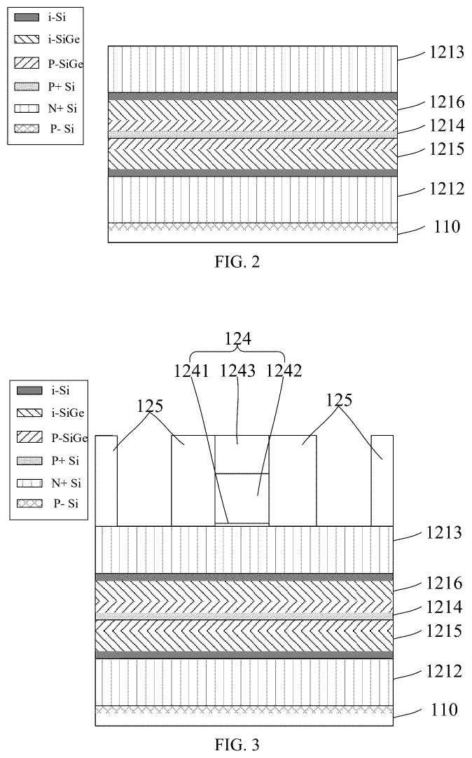

For example, as shown in FIG. 2, N-type or P-type well region implantation is performed on a suitable substrate 110 to obtain the corresponding device region for subsequent P-type or N-type transistor. For example, P-type implantation is performed for P-well/NMOS devices, and N-type implantation is performed for N-well/NMOS devices. The doping concentration may be adjusted according to the doping type. Taking P-well/NMOS devices as an example, on the well region (P−Si) of the substrate 110, the following materials are sequentially epitaxially stacked from bottom to top in the vertical direction of the semiconductor device to form a stack: heavily doped N-type silicon (N+Si), intrinsic silicon (i-Si), intrinsic germanium silicon (i-SiGe), thin heavily doped P-type germanium silicon (P+SiGe), thin heavily doped P-type silicon (P+Si), thin heavily doped P-type germanium silicon (P+SiGe), intrinsic germanium silicon (i-SiGe), intrinsic silicon (i-Si), and heavily doped N-type silicon (N+Si). The first layer of heavily doped N-type silicon and the first layer of intrinsic silicon are used to fabricate the source layer 1212. After thermal annealing, the first layer of intrinsic silicon is heavily doped through diffusion of heavily doped N-type silicon, so as to prevent diffusing N-type heavily doped silicon into the intrinsic channel through thermal annealing, prevent shortening the channel, and avoid the short channel effect. The intrinsic germanium silicon and the thin heavily doped P-type germanium silicon on the source layer 1212 are used to fabricate the first body contact sacrificial layer 1215 on the source layer 1212. The thin heavily doped P-type silicon is used to fabricate the body contact layer 1214. The intrinsic germanium silicon and the thin heavily doped P-type germanium silicon on the body contact layer 1214 are used to fabricate the second body contact sacrificial layer 1216. The last layer of intrinsic silicon and the last layer of heavily doped N-type silicon are used to fabricate the drain layer 1213. For example, the thickness of the thin layer may be adjusted according to the specific device performance requirements, so as to form a low doping region corresponding to the channel layer through thermal annealing. The heavy doping concentration is in a range of 1e19 cm⁻³ to 1e20 cm⁻³, which may be adjusted according to specific device performance requirements.

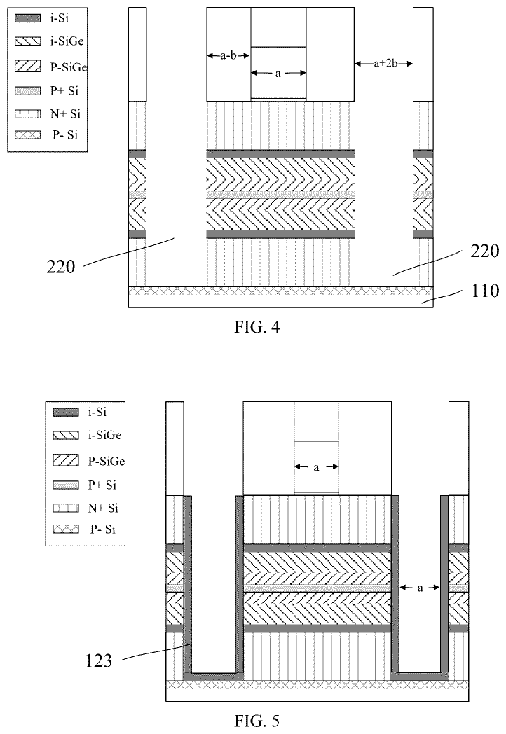

As shown in FIG. 3, a thin oxide layer 1241, a mandrel sacrificial layer 1242 (which may be made of amorphous silicon), and a second etching sacrificial layer 1243 (which may be made of silicon oxide) are further deposited on the stack to form a patterned structure 124. Then, a spacer 125 is fabricated on both sides of patterned structure 124 by using the patterning process and the silicon oxide spacer process in sequence, so as to define the source/drain region below the spacer 125. As shown in FIG. 4, a width of the mandrel sacrificial layer 1242 is the distance (a) between the transistors to be fabricated. For an array of devices with equal width and equal spacing, the distance between transistors is identical to the width of the transistor. Therefore, the width (a) of the transistor is the sum of the width of the spacer 125 and the thickness (b) of the channel layer 122. In this way, after depositing the channel layer 122 in the first trench 210, the width of the remaining space in the first trench 210 may be identical to the width of the transistor, thereby ensuring the formation of the array of devices with equal width and equal spacing, where the array of devices with equal width and equal spacing refers to that the widths of the devices are identical to each other, and the distances between any adjacent devices are identical to each other. The device spacing and the device width may be set to any value as desires, and they may be the same or different. In this embodiment, the device spacing and the device width are identical, for example, the transistor spacing or the transistor width is about 15 nm.

As shown in FIGS. 3 and 4, etching is performed with the spacer 125 as a barrier layer to achieve the pattern transfer of the stack below, so as to form the first trench 210. As shown in FIGS. 4 and 5, a single crystal Si is epitaxially grown on an inner surface of the formed first trench 210 to form a single crystal channel 123. A width of the first trench 210 is the sum of the width (a) of the mandrel sacrificial layer 1242 and twice (2b) the thickness of the channel layer 122, which ensures that the distance between the two epitaxial single crystal channels 123 is also the width (a) of the mandrel sacrificial layer 1242. As shown in FIG. 6, dopants in the stack formed in FIG. 2 are driven into the epitaxial single crystal channel 123 through moderate thermal annealing, so as to form a channel layer 122 with low doping at both ends and uniform high doping in the middle. After filling the first etching sacrificial layer 160 and chemical mechanical polishing for planarization, the surface of the mandrel sacrificial layer 1242 is exposed. After the mandrel sacrificial layer 1242 is removed by wet etching, the Si layer and the SiGe layer in the stack are etched by using the sidewall formed by removing the mandrel sacrificial layer 1242 as a mask. The entire SiGe layer is exposed on the side, forming a second trench 220 deep to the substrate 110 and a source/drain structure 121. After filling the sacrificial layer, a device precursor as shown in FIGS. 7 and 8 is formed.

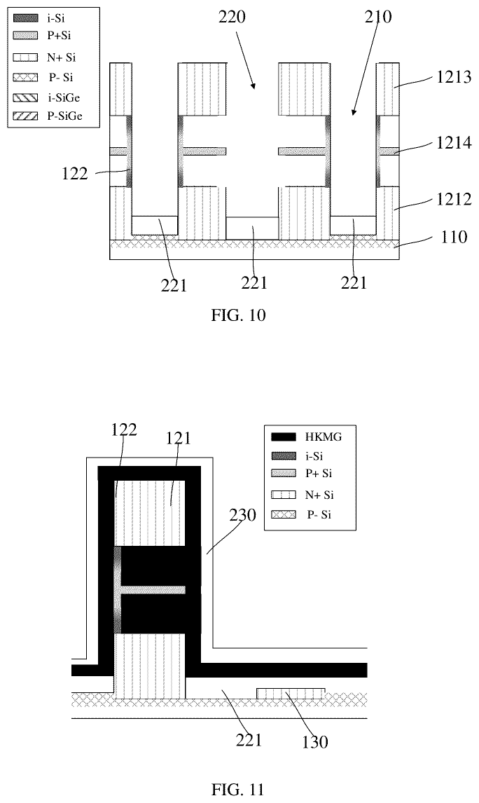

A single device region is defined on the device precursor through photolithography, as shown in FIG. 8, the angle α between the photoresist pattern 240 and the vertical direction (the second direction where the bit line 130 extends) in the figure is about 60°. For ease of understanding, only two photoresist patterns 240 are shown in FIG. 8, while in practice, multiple photoresist patterns are evenly spaced throughout the plane. In addition, in order to facilitate the understanding of the positional relationship between the source/drain structure 121 and the trench, the first etching sacrificial layer 160 on the source/drain structure 121 is omitted in the figure, while in practice, the first etching sacrificial layer 160 is arranged on the source/drain structure 121 in order to protect the source/drain structure 121, as shown in FIG. 7, the first etching sacrificial layer 160 may cover the source/drain structure 121. The region covered by the photoresist 240 is defined as the required device unit region, the etching sacrificial layer outside of the photoresist 240 is removed, and only a part of the source layer 1212 connected at the bottom is retained as the bit line 130. As shown in FIG. 9, after removing the photoresist 240, the first etching sacrificial layer 160 is filled and etched back to remove the remaining first etching sacrificial layer 160, and a dielectric layer 221 is deposited on the substrate 110 and the bit line 130 in the second trench 220, so as to form the channel region 190 between the source/drain structures 121. As shown in FIG. 10, SiGe, also known as the bulk contact sacrificial layer, is removed by selective dry or wet etching, so as to form a device structure with a thin body contact layer 1214 and the channel with uniformly doped wide channel center and two lightly doped ends.

In step 303, a word line extending in a first direction and perpendicular to the bit line is formed on the dielectric layer.

In this embodiment, the word line extending in the first direction is formed on the dielectric layer covering the bit line, so as to achieve the construction of isolated and vertically intersecting layout of bit lines and word lines, resulting in a relatively small overlap area between bit lines and word lines, effectively reducing the parasitic capacitance between bit lines and word lines, and reducing electric field scattering and leakage. Furthermore, more transistors may be accommodated on the substrate with a given area, facilitating the positioning and operation of each transistor through corresponding bit lines and word lines, thereby achieving a higher storage density.

Furthermore, as a refinement and extension of the specific implementation method of the above embodiment, in order to fully describe the specific implementation process of this embodiment, the step 303 may, for example, include: sequentially depositing the high dielectric constant material and the metal gate material on the dielectric layer; and etching the high dielectric constant material and the metal gate material on the dielectric layer according to a word line region, so as to form the word line.

In step 304, a base line is formed in the body contact cavity and the channel region.

The base line extends in the second direction and is parallel to the bit line, the base line is in contact with the body contact layer, and the base line is isolated from the source layer, the drain layer, and the word line.

In this embodiment, the base line is led out from the internal body contact region of the transistor to ensure that the base line is connected to the transistor, and the base line is used as a carrier channel to transport carriers induced by different vertical transistors. Through the above technical solution, on the one hand, the problem of unstable threshold voltage of vertical transistors caused by the presence of excess charge carriers is avoided, so that the device has an ultra-low off-state current in a wide range of gate control voltages, the floating body effect of the semiconductor structure is effectively reduced, forward conduction of the parasitic PN junction is prevented, and the leakage current is significantly reduced; on the other hand, the source, the gate, and the drain are provided in the vertical direction perpendicular to the substrate surface, and a part of the base line is located in the internal body contact region of the transistor, without occupying additional area, while the bit line, the word line, and the base line are provided in an overlapping manner in the channel region in the first direction, and the bit line, the word line, and the base line are isolated by the isolation material, eliminating the inherent distance between the bit line, the word line, and the base line in the DRAM array structure of existing gate-all-around transistors, which is conducive to the miniaturization of semiconductor devices.

Furthermore, as a refinement and extension of the specific implementation method of the above embodiment, in order to fully describe the specific implementation process of this embodiment, the step 304 may, for example, include: growing an etching stop layer on the word line and the surrounding gate layer; removing a part of the etching stop layer covering the word line, so as to form a gap exposing the word line; filling the body contact cavity and the gap with an isolation layer, and keeping the body contact layer exposed outside the isolation layer; depositing a conductive material on the transistor and the channel region; and removing a part of the conductive material in contact with the transistor and a part of the conductive material covering the etching stop layer, so as to form the base line.

For example, as shown in FIG. 11, HKMG ALD (High-k Metal Gate Atomic Layer Deposition) is performed on the dielectric layer 221 and the source/drain structure 121, forming the VGAA (Vertical Gate-All-Around) structure of the device. Afterwards, a word line region is defined through photolithography. Anisotropic etching is performed in the word line region, the photoresist is removed, and an etching stop layer 230 is grown on the VGAA structure. The etching stop layer 230 may be made of silicon nitride (SiN). The third etching sacrificial layer 170 is filled to protect the device, and chemical mechanical polishing is performed for planarization.

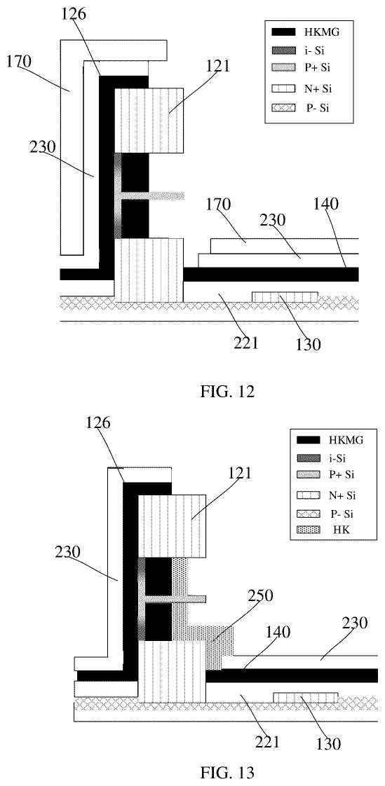

As shown in FIG. 12, the third etching sacrificial layer 170 on a side of the channel layer 122 is protected by the photoresist 240, and the exposed third etching sacrificial layer 170 is removed to a certain depth. After removing the photoresist, isotropic etching is performed again to sequentially remove the metal gate and the high dielectric material, so as to expose a part of the word line 140, the source layer 1212, the drain layer 1213, and the body contact layer 1214. At this point, the remaining high dielectric material and metal gate connected to the source/drain structure 121 and the channel layer 122 form the surrounding gate layer 126 of the transistor, and the remaining high dielectric material and metal gate in the channel region 190 form the word line 140. The metal gate may include layers that modulate the work function (such as AlO) and conductive materials (such as W, Al).

As shown in FIG. 13, after performing HK-ALD again, anisotropic high dielectric material etching and a small amount of isotropic etching are sequentially performed to expose the body contact layer 1214, so as to form an isolation layer 250. Finally, the exposed third etching sacrificial layer 170 is removed by wet etching.

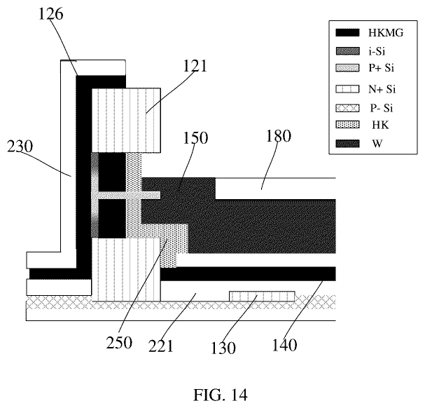

As shown in FIG. 14, a conductive material, such as tungsten, is deposited in the channel region 190 to deposit the base line 150, a fourth etching sacrificial layer 180 is etched back, and the shape of the base line 150 is protected through the fourth etching sacrificial layer 180. The etching stop layer 230 and the fourth etching sacrificial layer 180 are used as stop layers for etching back. After removing the exposed fourth etching sacrificial layer 180, the remaining tungsten on the etching stop layer 230 that may be connected to the body contact layer 1214 forms the base line 150. The base line 150 is parallel to the bit line 130, and the base line 150 is defined by photoetching, forming all electrical structures in the front and middle sections as shown in FIG. 1. The word line 140 extends in the first direction and is perpendicular to the bit line 130 and the base line 150, while the bit line 130 and the base line 150 are parallel to each other and extend in the second direction perpendicular to the first direction.

For example, the top n-Si may be removed through anisotropy to ensure no short circuit. The material of the etching sacrificial layer in embodiments may be silicon oxide, silicon nitride, silicon oxynitride, silicon oxycarbide, etc. Conductive materials may also be metals such as aluminum. Tungsten (W) is used as an example and shown in FIGS. 1 and 14. In addition, metal gate materials may also be used to fabricate the base line.

It should be noted that the size of the sequence numbers of various steps in the above embodiments does not imply the order of execution. The execution order of various processes should be determined by its function and internal logic, and should not constitute any limitation on the implementation process of embodiments of the present disclosure.

Those skilled in the art may understand that the accompany drawings are only schematic diagrams of a preferred implementation scenario, and the modules or processes in the accompany drawings are not necessarily necessary for implementing the present disclosure.

In the description of this specification, the terms “an embodiment”, “some embodiments”, “specific embodiments”, etc. refer to the specific features, structures, materials, or characteristics described in conjunction with embodiments or examples are included in at least one embodiment or example of the present disclosure. In this specification, the illustrative expressions of the above terms may not necessarily refer to the same embodiments or examples. Moreover, the specific features, structures, materials, or characteristics described may be combined in any one or more embodiments or examples in a suitable manner.

The above numbers of the present disclosure are for description only and do not represent the advantages or disadvantages of the implementation scenario. The above disclosed content is only a few specific implementation scenarios of the present disclosure, but the present disclosure is not limited to this. Any changes that may be conceived by those skilled in the art should fall within the scope of protection of the present disclosure.

What is claimed is:

1. A semiconductor device, comprising:
a substrate;
a plurality of transistors on the substrate, wherein a channel region is between adjacent transistors among the plurality of transistors, each of the plurality of transistors comprises a surrounding gate layer, a source layer, a drain layer, and a body contact layer, the surrounding gate layer is adjacent to the source layer and the drain layer, a body contact cavity is formed between the source layer and the drain layer, an opening of the body contact cavity is located on a side of the transistor away from the surrounding gate layer, and the body contact layer is located within the body contact cavity;
a bit line at a bottom of the channel region and extending in a second direction, wherein the transistor is coupled to the bit line;
a word line on a dielectric layer of the channel region, extending in a first direction and perpendicular to the bit line, wherein the dielectric layer covers the substrate and the bit line; and
a base line in the body contact cavity and the channel region, wherein the base line is in contact with the body contact layer and isolated from the source layer, the drain layer, and the word line, and the base line extends in the second direction and is parallel to the bit line.

2. The semiconductor device according to claim 1, wherein each of the plurality of transistors further comprises:
a channel layer on a side of the transistor away from the opening of the body contact cavity,
wherein the channel layer comprises a first part, a second part, and a third part, the first part of the channel layer is connected to the body contact layer, the third part of the channel layer is connected to the source layer and the drain layer, and the second part of the channel layer is located between the first part of the channel layer and the third part of the channel layer, and wherein a doping concentration of the first part of the channel layer is greater than a doping concentration of the second part of the channel layer in a vertical direction of the semiconductor device; and
wherein a height of the first part of the channel layer is greater than a height of the body contact layer in the vertical direction of the semiconductor device, and a doping type of the channel layer is same as a doping type of the source layer, the drain layer, or the body contact layer connected to the channel layer.

3. The semiconductor device according to claim 1,
wherein the channel region extends in the second direction; and
wherein widths of the plurality of transistors in the first direction are equal to each other;
distances between the transistors among the plurality of transistors in the first direction are equal to each other, and
distances between bit lines in the first direction are equal to each other, and the distance between the bit lines is less than 50 nm.

4. A method of manufacturing a semiconductor device, comprising:
forming a plurality of transistors arranged in a matrix on a substrate, wherein a channel region is formed between adjacent transistors among the plurality of transistors, each of the plurality of transistors comprises a surrounding gate layer, a source layer, a drain layer, and a body contact layer, the surrounding gate layer is adjacent to the source layer and the drain layer, a body contact cavity is formed between the source layer and the drain layer, an opening of the body contact cavity is located on a side of the transistor away from the surrounding gate layer, and the body contact layer is located within the body contact cavity;
forming a bit line extending in a second direction at a bottom of the channel region, and depositing a dielectric layer to cover the substrate and the bit line;
forming a word line extending in a first direction and perpendicular to the bit line on the dielectric layer; and
forming a base line in the body contact cavity and the channel region, wherein the base line extends in the second direction and is parallel to the bit line, the base line is in contact with the body contact layer, and the base line is isolated from the source layer, the drain layer, and the word line.

5. The method according to claim 4, wherein forming the plurality of transistors arranged in the matrix on the substrate and forming the bit line extending in the second direction at the bottom of the channel region comprises:
preparing a device precursor on the substrate, wherein the device precursor comprises a plurality of source/drain structures distributed in the first direction and a first etching sacrificial layer, a first trench or a second trench deep to the substrate is provided between adjacent source/drain structures among the plurality of source/drain structures, the first etching sacrificial layer covers the source/drain structure and fills the first trench and the second trench, each of the plurality of source/drain structures comprises the source layer, the drain layer, a body contact sacrificial layer, and the body contact layer, the body contact sacrificial layer is located between the source layer and the drain layer, the body contact layer is sandwiched in the body contact sacrificial layer, and a channel layer is formed on an inner wall of the first trench;
etching the source/drain structure located on a designated side of the second trench and the first etching sacrificial layer according to a device region, and retaining a part of the source layer on the substrate as the bit line;
etching a remaining part of the first etching sacrificial layer, and depositing the dielectric layer on the substrate and the bit line to form the channel region;
removing the body contact sacrificial layer in the source/drain structure, so as to form the body contact cavity having the opening on a side of the source/drain structure away from the channel layer; and
depositing a high dielectric constant material and a metal gate material in the body contact cavity and on a surface of the source/drain structure, and removing a part of the high dielectric constant material and a part of the metal gate material in the body contact cavity to have a predetermined width and a part of the high dielectric constant material and a part of the metal gate material on the source/drain structure close to the opening of the body contact cavity to obtain the surrounding gate layer, so as to form the transistor, wherein the body contact layer is exposed outside the surrounding gate layer.

6. The method according to claim 5, wherein the preparing a device precursor on the substrate comprises:
sequentially growing, in a vertical direction of the semiconductor device, the source layer, a first body contact sacrificial layer, the body contact layer, a second body contact sacrificial layer, and the drain layer on the substrate, so as to form a stack;
forming a patterned structure on the stack by using a patterning process, and fabricating a spacer on both sides of the patterned structure, wherein the patterned structure comprises a mandrel sacrificial layer and a second etching sacrificial layer sequentially grown;
etching the stack with the spacer as a barrier, so as to form the first trench deep to the substrate;
epitaxially growing the channel layer on the inner wall of the first trench;
polishing the second etching sacrificial layer to expose the mandrel sacrificial layer, and removing the mandrel sacrificial layer;
etching the stack with the spacer obtained after removing the mandrel sacrificial layer as a mask, so as to form the second trench deep to the substrate and the source/drain structure; and
depositing the first etching sacrificial layer on the first trench, the second trench, and the source/drain structure to form the device precursor.

7. The method according to claim 6, wherein the epitaxially growing the channel layer on the inner wall of the first trench comprises:
epitaxially growing a single crystal channel on the inner wall of the first trench; and
performing a thermal annealing treatment on the single crystal channel to drive dopants in the stack into the single crystal channel, so as to form the channel layer.

8. The method according to claim 6,
wherein an angle between the device region and the second direction is in a range of 55° to 65°; and
wherein a width of the mandrel sacrificial layer in the first direction is a distance between the transistors in the first direction, a width of the transistor in the first direction is a sum of a width of the spacer in the first direction and a thickness of the channel layer in the first direction, a width of the first trench in the first direction is a sum of the width of the mandrel sacrificial layer and twice the thickness of the channel layer, and the distance between the transistors is less than 50 nm.

9. The method according to claim 4, wherein the forming a word line extending in a first direction and perpendicular to the bit line on the dielectric layer of the channel region comprises:
sequentially depositing a high dielectric constant material and a metal gate material on the dielectric layer; and
etching the high dielectric constant material and the metal gate material on the dielectric layer according to a word line region, so as to form the word line.

10. The method according to claim 4, wherein the forming a base line in the body contact cavity and the channel region comprises:
growing an etching stop layer on the word line and the surrounding gate layer;
removing a part of the etching stop layer covering the word line, so as to form a gap exposing the word line;
filling the body contact cavity and the gap with an isolation layer, and keeping the body contact layer exposed outside the isolation layer;
depositing a conductive material on the transistor and the channel region; and
removing a part of the conductive material in contact with the transistor and a part of the conductive material covering the etching stop layer, so as to form the base line.
